(19) United States
(12) Patent Application Publication
(10) Pub. No.: US 2010/0173067 A1
(43) Pub. Date: Jul. 8, 2010

(54) FILM FORMING APPARATUS AND FILM FORMING METHOD

(75) Inventors: Nobutaka Ukigaya, Mobara-shi (JP); Kiyoshi Kuramochi, Chiba-shi (JP); Takahide Onuma, Kawasaki-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/652,698

(22) Filed: Jan. 5, 2010

(30) Foreign Application Priority Data
Jan. 7, 2009 (JP) 2009-001421

(51) Int. Cl. B05D 5/06; C23C 16/00; C23C 16/44

(52) U.S. Cl. 427/66; 118/724; 427/248.1

(57) ABSTRACT

An apparatus includes a holding mechanism that holds a substrate, a material container where a film-forming material is gasified, a release port for releasing the gasified film-forming material toward the substrate; a material container heating unit for heating the material container, a transport pipe that is detachably linked to the material container by a linking portion and serves to transport the gasified film-forming material from the material container to the release port, a transport pipe heating unit for heating a remaining zone of the transport pipe other than a portion in a vicinity of the linking portion, and a linking portion heating unit that is disposed independently from the transport pipe heating unit and serves for heating the portion of the transport pipe in the vicinity of the linking portion.

### BACKGROUND OF THE INVENTION

1. Field of the Invention

The present invention relates to a film forming apparatus and a film forming method for forming a thin film.

2. Description of the Related Art

Organic EL devices (organic field emission devices) have attracted attention as display devices suitable for full-color flat panel display. An organic EL device is a spontaneous emission device in which an organic compound having fluorescent or luminescent property is electrically excited and caused to emit light. Such a device features a high luminance, a large angle of viewing, plane emission, and ability to perform multicolor emission in a thin configuration.

In recent years, a variety of improvements have been introduced in manufacturing apparatuses for organic EL displays carrying such organic EL devices to may be further increasing the productivity.

A vacuum vapor deposition apparatus is known as a film forming device in which a thin film is formed on a substrate. A typical vacuum vapor deposition apparatus has a configuration in which a film formation source disposed in a vacuum chamber is heated and evaporated material released from an evaporation port of the film formation source is deposited on a substrate that is also disposed in the vacuum chamber.

Film formation using the above-descried film forming apparatus is conducted in a process of forming an organic material layer or an electrode layer constituting the organic EL device. For example, when mass production of organic EL displays is carried out, the supply of material to the aforementioned film formation source is an important factor in ensuring good productivity.

Accordingly, U.S. Pat. No. 4,325,986 discloses a film forming apparatus in which a detachable film formation source is disposed outside a film forming chamber, a manifold provided with a plurality of nozzles that serve as release ports is disposed inside the film forming chamber, and a vapor transport pipe including a valve is connected between the film formation source and the manifold.

With such an apparatus, when a new material is supplied, the vapor flow from the film formation source to the nozzle is initially shut down with a valve and when the evaporation or sublimation of the material in the film forming chamber has stopped, the film formation source is detached from the transport pipe outside the film forming chamber. The replacement of the material supply or material container is thus performed.

However, with the above-described conventional technique, the following technical issues still remain when high productivity in mass production of organic EL displays is pursued.

The issue associated with the conventional apparatus disclosed in U.S. Pat. No. 4,325,986 is that the apparatus downtime used to replenish the material in the material container or replace the material container provided in the film formation source is long, thereby reducing the operation efficiency of the apparatus.

Reasons causing a long downtime of the apparatus are described below.

First, the cooling efficiency of the material container is low. This is because the temperature effect of the transport pipe connecting the material container to the discharge is conveyed by radiation or conduction to the material container.

It is obvious that for vapor deposition to be stopped, the temperature of the vapor deposition material accommodated in the material container has to be made equal to or less than the evaporation temperature. However, because the temperature effect of the transport pipe connecting the material container to the release ports is reached by radiation or conduction to the material container even when the output of a heating unit of the material container is stopped, a long time is used for the temperature of the material container to reach the temperature at which the evaporation is stopped even after the heating of the material container has been stopped.

Meanwhile, where the outputs of the heating unit of the material container and transport pipe are stopped at the same time to shorten the cooling time of the material container, the vapor from the material container can condensate inside the transport pipe in the cooling process.

In the operations performed to stop the apparatus, stopping the evaporation from the material container, without causing the concentration of vapor inside the transport pipe, is performed to stabilize the vapor deposition rate rapidly after the operation is restarted.

### SUMMARY OF THE INVENTION

In order to attain the above-described aspect, an apparatus in accordance with the aspect of the invention includes: a holding mechanism that holds a substrate; a material container where a film-forming material is gasified; a release port for releasing the gasified film-forming material toward the substrate; a material container heating unit for heating the material container; a transport pipe that is detachably linked to the material container by a linking portion and serves to transport the gasified film-forming material from the material container to the release port; a transport pipe heating unit for heating a remaining zone of the transport pipe other than a portion in a vicinity of the linking portion; a linking portion heating unit that is disposed independently from the transport pipe heating unit and serves for heating the portion of the transport pipe in the vicinity of the linking portion; and a control unit for controlling the transport pipe heating unit and the linking portion heating unit.

Further features of the present invention will become apparent from the following description of exemplary embodiments with reference to the attached drawings.

### BRIEF DESCRIPTION OF THE DRAWINGS

FIG. 1 is a schematic diagram illustrating the film forming apparatus of the first embodiment;

FIG. 2 is a schematic diagram illustrating the film forming apparatus of the first embodiment;

FIG. 3 is a processing diagram illustrating a film formation process of the second embodiment;

FIG. 4 is a graph illustrating how the evaporation rate and temperature change with time in the second embodiment;

FIG. 5 is a schematic diagram illustrating the film forming apparatus of the third embodiment;

FIG. 6 is a graph illustrating how the evaporation rate and temperature change with time in the third embodiment;

FIG. 7 is a schematic diagram illustrating the film forming apparatus of the fourth embodiment; and

FIG. 8 is a schematic diagram illustrating the film forming apparatus of the fifth embodiment.

### DESCRIPTION OF THE EMBODIMENTS

The embodiments of the invention will be explained below with reference to the appended drawings.

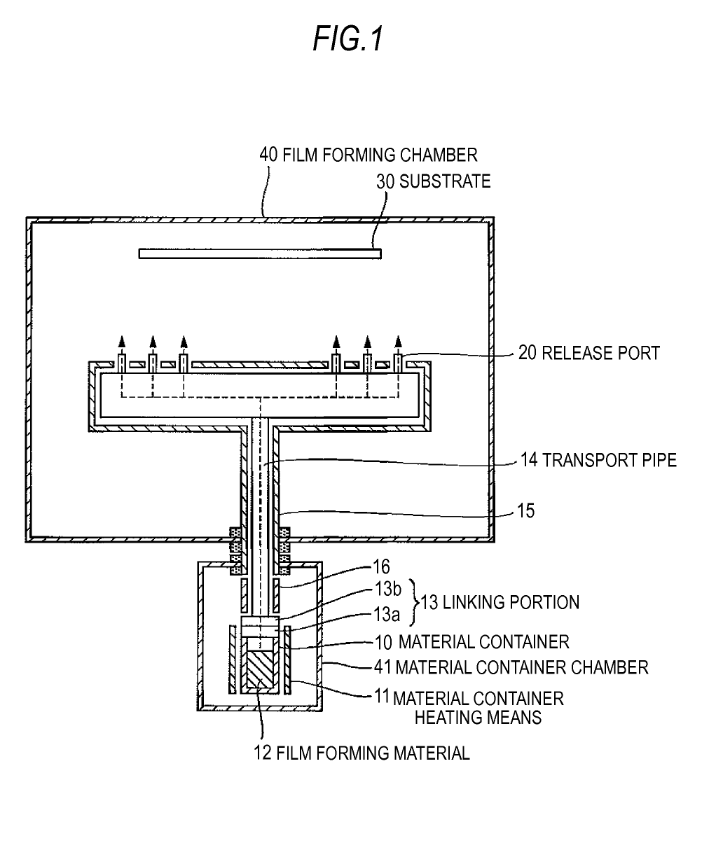

FIG. 1 illustrates a film forming apparatus of the first embodiment.

In the film forming apparatus of the present embodiment, a film-forming material (vapor) gasified in a material container 10 is released from release ports 20 toward a substrate 30 to form a film. A substrate holding mechanism that holds the substrate 30 and the release ports 20 are disposed inside a film forming chamber 40, the material container 10 is disposed inside a material container chamber 41, and the film-forming material 12 is heated and gasified by a material container heating unit 11. The material container 10 is detachably linked to a transport pipe 14 by a linking portion 13.

Inside the film forming chamber 40, a plurality of release ports 20 that release the gasified film-forming material are disposed opposite the substrate 30. The release ports 20 communicate with the material container 10 disposed in the material container chamber 41 via the transport pipe 14. Both the film forming chamber 40 and the material container chamber 41 are vacuum containers.

The material container 10 and transport pipe are provided with linking members 13a and 13b constituting the linking portion 13 for detachably attaching the material container 10 to the transport pipe 14. A unit for independently controlling the temperature of the transport pipe 14 and material container 10 are provided therein. Thus, a transport pipe heating unit 15 is provided for heating the transport pipe 14, and a material container heating unit 11 is provided for heating the material container 10.

Further provided are a linking portion heating unit 16 for heating a portion of the transport pipe 14 in the vicinity of the linking portion 13 with the material container 10 independently from the remaining zone other than the vicinity of the linking portion, and a control unit for controlling the linking portion heating unit 16 and the transport pipe heating unit 15 independently from each other.

In the process of stopping the evaporation in the material container 10, the linking portion heating unit 16 lowers the temperature together with the material container heating unit 11. As a result, the cooling efficiency of the material container 10 can be increased and the evaporation can be rapidly stopped.

When the evaporation in the material container 10 is started, the linking portion heating unit 16 raises the temperature together with the material container heating unit 11. The temperature control may be conducted such that the temperature in the vicinity of the linking portion become higher than the temperature of the material container 10 and the remaining zone of the transport pipe 14.

As a result, a temperature gradient is created in the height direction of the material container 10 and the side close to the evaporation surface of the film-forming material 12 loaded into the material container 10 becomes higher. In other words, the evaporation surface can be rapidly heated and no unnecessary heat is provided to the film-forming material 12 far from the evaporation surface, thereby making it possible to reduce the thermal load on the film-forming material 12.

No limitation is placed on the above-described structure, provided that the sealing mechanism prevents the material from leaking between the material container 10 and the transport pipe 14 inside the material container chamber 41 that has a reduced-pressure atmosphere.

For example, a linked structure in which the material container and the transport pipe are integrated using a mechanical clamp, or a linked structure in which an O-ring is inserted between the material container and the transport pipe and the two are sealed by tightening the screws so as to crush the O-ring can be used. Further, a structure can be also used in which the transport pipe and material container are integrated by pushing up the lower surface of a crucible. In addition, generally known seal structures and sealing materials can be used.

With the film forming apparatus shown in FIG. 1, condensation of the film-forming material inside the transport pipe can be avoided, the evaporation can be started and stopped within a short time, and the material container replacement operation can be performed with improved efficiency, thereby increasing the apparatus operation efficiency. Further, in a period in which the film is not formed, no unnecessary heat is provided to the film-forming material located inside the material container. The additional effect is that thermal damage of the film-forming material is reduced.

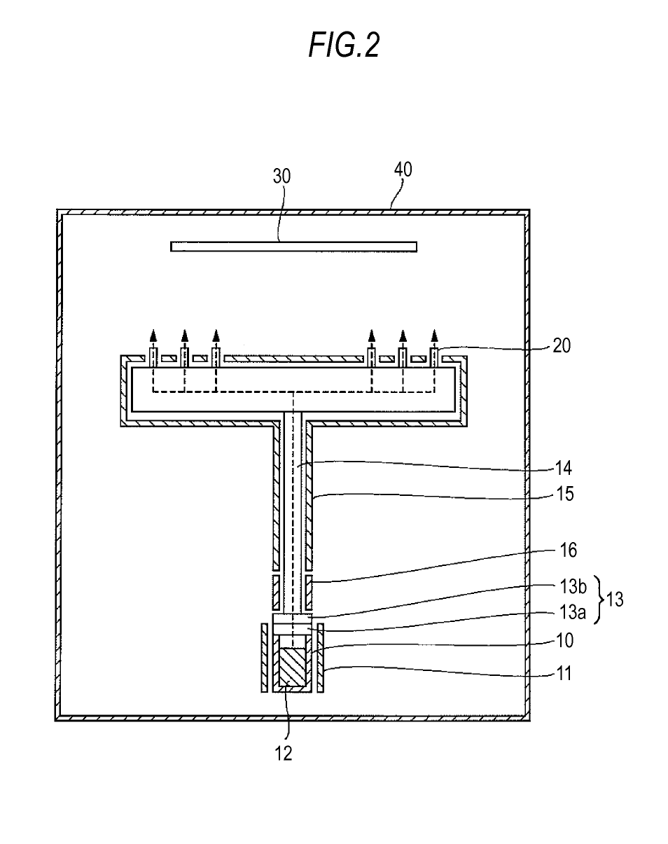

FIG. 2 shows a film forming apparatus of the second embodiment.

The film forming apparatus of the second embodiment differs from the film forming apparatus shown in FIG. 1 in that the material container 10 is disposed inside the film forming chamber 40 and the material container chamber 41 is omitted.

With such a configuration, there are no places where the transport pipe 14 comes into contact with a wall surface constituting the film forming chamber 40. Therefore, heat can be prevented from escaping from the transport pipe 14 to the wall surface. As a result, uniform temperature distribution in the transport pipe is easily attained without a complex temperature adjustment. Further, the pipe can be shortened and therefore the pipe resistance can be reduced.

Therefore, uniform distribution of temperature in the transport pipe 14 easily prevents local condensation inside the pipe, and the reduced pipe resistance can relax a thermal load on the material and reduce the danger of decomposition.

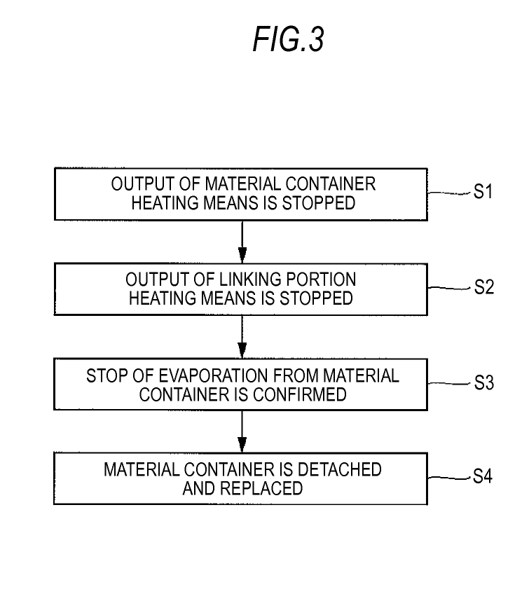

FIG. 3 is a flowchart illustrating the process of stopping the formation of a film in the film forming apparatus shown in FIG. 2.

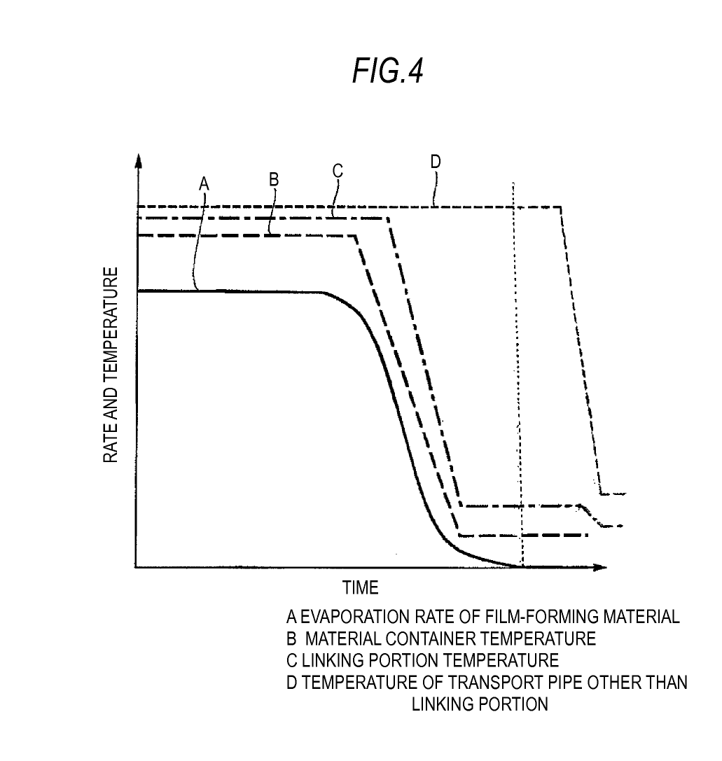

FIG. 4 shows a graph illustrating how the evaporation rate and temperature of each component change with time in each process shown in FIG. 3.

As shown by a flowchart in FIG. 3, in order to stop the formation of a film, the outputs of the material container heating unit 11 and the linking portion heating unit 16 are gradually stopped in order to lower the temperature of parts that are temperature adjusted by these heating units (steps S1 and S2). At the same time, the temperature of the film-forming material itself that is located inside the material container is lowered and the evaporation rate is rapidly reduced. After the evaporation has stopped (step S3), the material container is detached (step S4), and the film-forming material can be replenished or the material container can be replaced.

FIG. 4 shows how the evaporation rate and temperature of each component change with time in the above-described process. However, in the temperature control conducted only to stop the evaporation, it is possible not to reduce the temperature of the transport pipe in the zones other than the vicinity of the linking portion. Further, in a case where it is opening the film forming chamber to the atmosphere is performed in order to replace the material container, heating of the zones other than the vicinity of the linking portion may be stopped after the evaporation rate has become zero and the temperature of the entire transport pipe may be lowered.

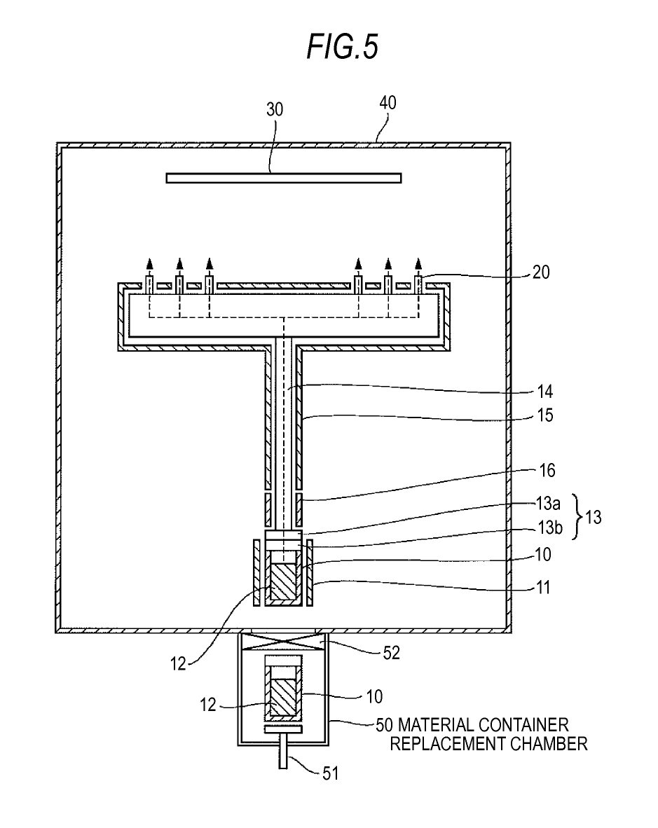

FIG. 5 shows a film forming apparatus of the third embodiment.

The film forming apparatus of the present embodiment includes a material container replacement chamber 50 that is disposed adjacently to the film forming chamber 40 and enables automatic replacement of the material container 10. In this film forming apparatus, it is not necessary to open the film forming chamber 40 to the atmosphere in order to replenish the material in the material container 10 or replace the material container 10. Therefore, it is not necessary to lower the temperature of the transport pipe heating unit 15 for heating the zone of the transport pipe 14 other than the vicinity of the linking portion in the process of stopping the formation of film.

Automatic replacement of the material container 10 will be described below in detail.

A material container holder 51 is disposed in the material container replacement chamber 50, and the material container 10 filled with the film-forming material 12 is in a standby state on the material container holder 51. In the standby mode, the material container replacement chamber 50 is maintained under vacuum or reduced pressure. The degree of vacuum should be the same as in the film forming chamber 40.

After the evaporation of the material container 10 has been stopped in the film forming chamber 40, the linking of the material container 10 and transport pipe 14 is canceled. A gate valve 52 located between the film forming chamber 40 and material container replacement chamber 50 is then opened, the material container 10 that has been used is withdrawn downward from the material container heating unit 11 and carried by an automatic robot into the material container replacement chamber 50. Another material container 10 that has been in a standby state inside the material container replacement chamber 50 is then carried by the automatic robot into the film forming chamber 40 and linked to the transport pipe 14.

After the linking has been completed, the gate valve 52 located between the film forming chamber and material container replacement chamber 50 is closed, the material container 10 is appropriately heated with the material container heating unit 11 or the linking portion heating unit 16, and the temperature of the material container 10 is adjusted to obtain the predetermined evaporation amount.

The material container 10 carried from the film forming chamber 40 into the material container replacement chamber 50 can be taken outside of the material container replacement chamber 50 in a state with the closed gate valve 52. In this case, another material container filled with the film-forming material can be introduced at the same time.

When the material container is taken out to the atmosphere from the material container replacement chamber 50, the film-forming material remaining inside the material container should be prevented from exposure to the atmosphere by closing the material container with a lid inside the material container replacement chamber 50.

When the material container is loaded from the atmosphere into the material container replacement chamber 50, the material container should be closed with a lid prior to loading to obtain an evacuated or reduced pressure state for preventing the film-forming material contained in the material container from exposure to the atmosphere.

In particular, an organic material constituting an organic EL device deteriorates especially easily under the effect of impurities such as oxygen and moisture. The impurities contained in the organic material also cause the deterioration of the organic material layer. Therefore, such deterioration should be reduced or avoided by preventing the film-forming material from exposure to the atmosphere.

A material container heating unit (not shown in the figure) may be disposed in the material container replacement chamber 50 and the material container in a standby state may be preheated to induce gas emission from the film-forming material.

Further, an observation window may be provided in the material container replacement chamber 50 to enable the observations of a state of the film-forming material inside the material container removed from the film forming chamber 40 and residual amount of the film-forming material. Alternatively, a measuring unit may be provided that can measure the residual amount of the film-forming material. An optical sensor or a weight measuring device can be used as the measuring unit.

In the apparatus shown in FIG. 5, one material container is located in a standby state inside the material container replacement chamber, but such configuration is not limiting, and a plurality of material containers filled with the same material or a plurality of material containers filled with different materials may be located therein. In a case where a plurality of material containers are located in a standby state inside the material container replacement chamber, it is assumed that any material container can be carried to the film forming chamber. In a case where different materials are in a standby state, different materials can be continuously used to form a film in the same film forming chamber.

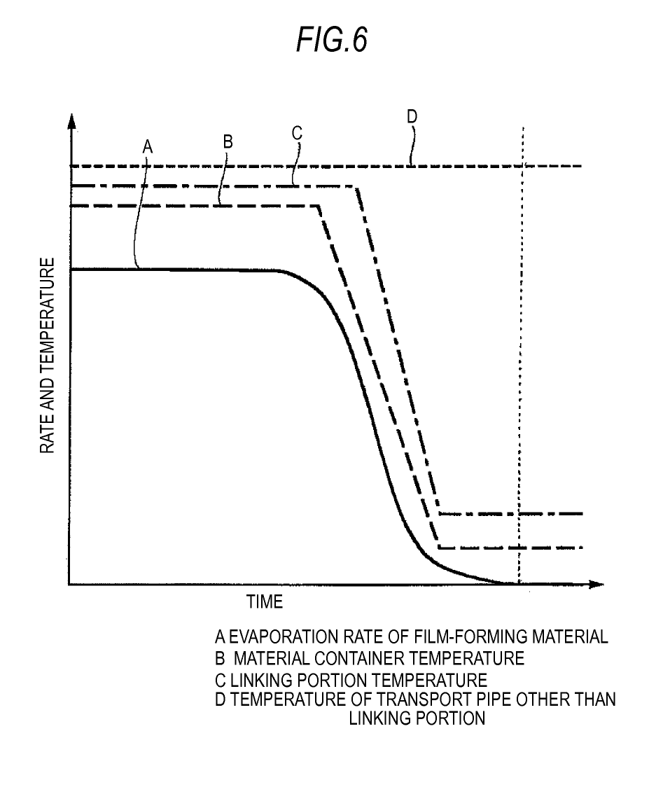

FIG. 6 is a graph illustrating how the evaporation rate and temperature change with time when film formation is stopped in the film forming apparatus shown in FIG. 5. In this case, it is possible to maintain continuously the temperature of the transport pipe other than the linking portion that has a comparatively high thermal capacity. In a case of the film forming apparatus shown in FIG. 5, the material container 10 can be automatically replaced without opening the film forming chamber 40 to the atmosphere. Therefore, the apparatus downtime period to load the film-forming material can be shortened. Another positive effect is that because the contamination of the inside of the film forming chamber can be inhibited, penetration of impurities into the vapor-deposited film (thin film) that is grown on the substrate 30 is inhibited.

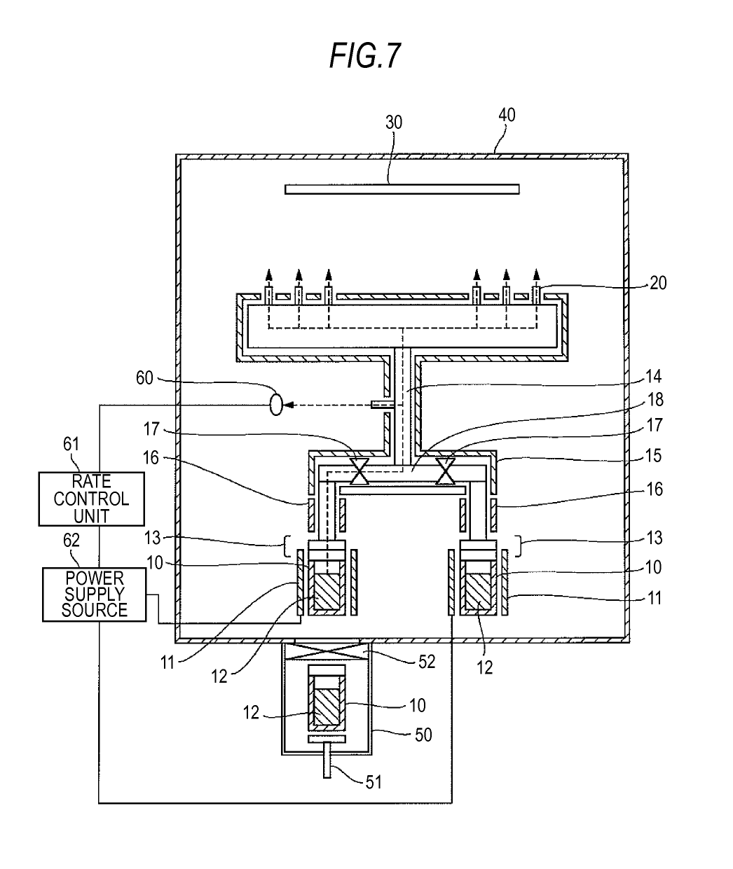

FIG. 7 shows a film forming apparatus of the fourth embodiment.

The film forming apparatus of the present embodiment differs from that shown in FIG. 5 in that a plurality of material containers 10 are disposed inside the film forming chamber 40 and connected to common release ports 20 by branch portions 18 of the transport pipe 14, each branch portion having a valve 17, thereby making it possible to switch the material container 10 that is used for forming the film. In this case, the material container 10 that is not used can be replaced at any time with the material container located outside the film forming chamber 40, thereby ensuring continuous film formation over a long period.

With the film forming apparatus of the present embodiment, the material container 10 can be also replaced rapidly as in the film forming apparatus shown in FIG. 5. Therefore, the capacity of the material container 10 that is repeatedly replaced may be small. As a result, the responsiveness of the temperature of the film-forming material 12 to the output of the material container heating unit 11 is improved, thereby making it possible to improve the control accuracy of evaporation rate. Further, it is not necessary to heat the film-forming material inside the material container for a long time and thermal load on the film-forming material can be reduced.

A detection unit 60 for detecting the flow rate (evaporation rate) of the film-forming material 12 gasified inside each material container 10 is disposed in a location such that the pipe resistance from each material container 10 to the detection unit 60 is the same and this detection unit is shared by a plurality of material containers 10. By so equalizing the pipe resistance with respect to the common detection unit 60, it is possible to obtain equal correlations between the evaporation amount of each material container 10 and evaporation amount detected by the detection unit 60 and facilitate the control.

A system is provided for controlling the evaporation amount in each material container 10. The flow rate confirmed by the detection unit 60 is transmitted to a rate control unit 61, a difference between this flow rate and the predetermined flow rate is found, a control signal is transmitted to a power supply source 62 to compensate for the difference, and each material container 10 is heated by the respective material container heating unit correspondingly to the output from the power supply source 62.

In the present embodiment, because the material container 10 can be replaced in a short cycle, without interrupting the formation of a film on the substrate 30, thermal damage of the film-forming material is reduced and film formation can be conducted continuously for a long time, while maintaining a high control accuracy of the evaporation amount.

In the configuration shown in FIG. 7, the material container replacement chamber 50 is disposed below the material container 10, but the location of the material container replacement chamber can be changed appropriately correspondingly to the size of the apparatus and installation site thereof.

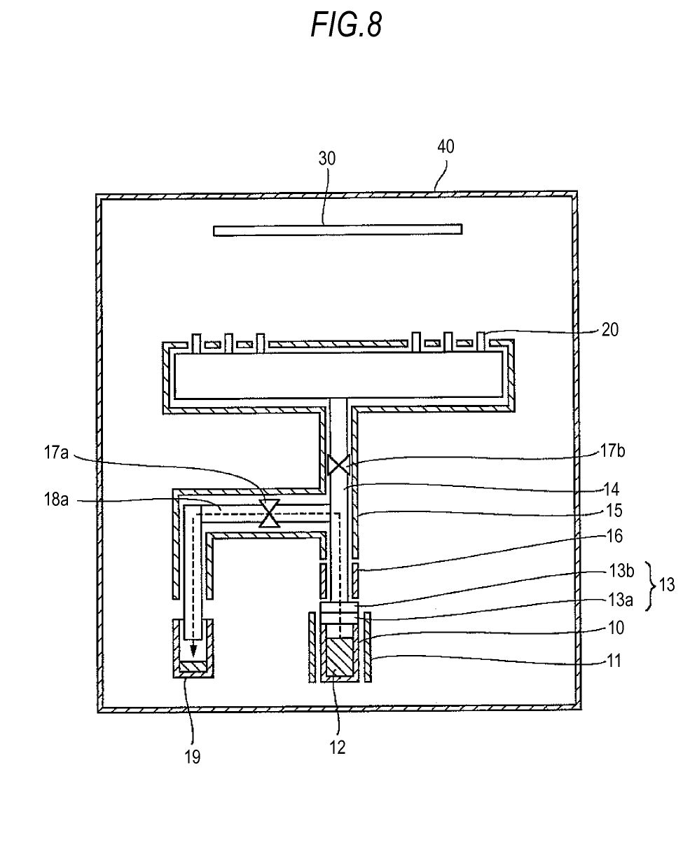

FIG. 8 shows a film forming apparatus of the fifth embodiment.

In the present embodiment, a recovery container 19 is disposed at the distal end of the branch pipe 18a branched off the transport pipe 14 that leads from the material container 10 to the release ports 20 facing the substrate 30. Further, a valve 17a is provided to shut down or open the flow of vapor to the branch pipe 18a, and a valve 17b is provided to shut down or open the flow of vapor to the transport pipe 14.

When the evaporation in the film forming apparatus is stopped, the flow to the release ports 20 is shut down by the valve 17b, the valve 17a is opened and the vapor flows toward the recovery container 19. At the same time, the heating of the material container heating unit 11 and the linking portion heating unit 16 is stopped. The film-forming material that has flown into the recovery container 19 is caused to condensate inside the recovery container 19, and back flow of the film-forming material into the transport pipe 14 is inhibited or prevented. In order to cause the condensation of the film-forming material inside the recovery container 19, the temperature inside of the recovery container is maintain at a temperature equal to or lower than the evaporation temperature of the film-forming material. For this purpose, in the present embodiment, the branch pipe 18a and recovery container 19 are not in contact with each other so as to make it difficult for the heat to propagate from the branch pipe 18a to the recovery container 19, and the conduction of heat from the branch pipe 18a to the recovery container 19 is inhibited. However, the example described herein places no limitation on the method or structure that inhibits the conduction of heat to the recovery container 19. For example, a generally known technique such as using a thermally insulating material or actively cooling with cooling water or the like can be also used.

With the film forming apparatus of the present embodiment, the formation of a film on the substrate 30 can be stopped instantaneously and evaporation from the material container 10 can be stopped rapidly. Further, the film-forming material recovered into the recovery container 19 can be reused, and the material utilization efficiency in this case is increased. In addition, when the film is not formed, contamination of the wall surface or deposition preventing plate of the film forming chamber 40 by the flying material can be reduced. As a result, the maintenance cycle of the film forming chamber 40 can be extended and the apparatus operation efficiency can be increased.

When the recovered material is reused, the material container 10 and recovery container 19 should be of the same shape and made of the same material and that the recovery container 19 could be linked to the transport pipe 14.

In the above-described embodiment, the substrate is disposed in the upper part of the film forming chamber and release ports are disposed therebelow, but such an arrangement of the substrate is not limiting and a longitudinal configuration may be used or the mutual arrangement of the substrate and release ports in the vertical direction may be reversed and the substrate may be disposed in the lower portion of the film forming chamber. In addition, the mutual arrangement of the substrate and release ports may be the same in the film formation period, or the substrate or film formation source may be rotated or moved correspondingly to specifications such as the substrate size of film formation time.

For example, a needle valve, a butterfly valve, or a gate valve is used as the valves 17, 17a, and 17b as flow rate control units. Alternatively, a selection can be made from structures that are capable of adjusting, opening, or shutting down the flow of the film-forming material (gas molecules), such as a shutter, correspondingly to the structure of the film forming apparatus or the adequate range. Further, a plurality of valves or shutters also may be used in combination.

With the above-described embodiments, it is possible to obtain a uniform temperature distribution in the transport pipe and reduce the pipe resistance. More specifically, the uniform distribution of temperature in the transport pipe makes it possible to inhibit or prevent local condensation inside the pipe. Further, the reduction in pipe resistance relaxes a thermal load on the material, and can inhibit the material modification or changes such as decomposition caused by thermal damage.

Further, the evaporation can be stopped and started within a short time, the operation of replenishing the material in the material container or replacing the material container can be realized with increased efficiency and therefore the operation efficiency of the apparatus can be increased.

Because the material container linked to the transport pipe can be continuously and automatically replaced under vacuum, the cycle of the material replenishment and material container replacement operation can be shortened. As a result, the material container can be reduced in volume, the responsiveness of the film-forming material temperature to the output of the material container heating unit is improved, and control accuracy of the evaporation rate can be increased.

Because the material container can be repeatedly replaced even during the long-term continuous film formation operation, it is not necessary to expose the film-forming material to a high temperature for a long time and a thermal load on the film-forming material in the manufacturing process can be further reduced.

As a result, in the process of manufacturing an organic EL panel that involves film formation steps using different materials, the productivity of the process can be increased and the decrease in yield caused by thermal damage of the film-forming material can be reduced, thereby making it possible to reduce the product cost. Further, the recovered film-forming material can be reused, thereby reducing the production cost.

### Example 1

In the present example, one of organic compound layers constituting an organic EL panel is formed by using the apparatus shown in FIG. 2.

The film forming chamber 40 is provided with the material container 10 in which the film-forming material 12 is gasified, the transport pipe 14, a plurality of release ports 20 for releasing the vapor toward the substrate 30, and the linking portion 13 that enables the detachment of the material container from the transport pipe 14 and replacement of the material container. Three heating units are provided in a vapor channel leading from the material container 10 to the release ports 20. These heating units are the material container heating units 11 for gasifying the film-forming material 12 located in the material container 10, the linking portion heating units 16 for adjusting the temperature of the transport pipe in the vicinity of the linking portion 13, and the transport pipe heating units 15 for heating the transport pipe 14 downstream of the vicinity of the linking portion 13. The film forming chamber 40 is evacuated by an evacuation unit to a vacuum degree of 10⁻⁴ Pa to 10⁻⁶ Pa.

A detection unit (not shown in the figure) is disposed for detecting the film formation rate of the film-forming material released from the plurality of release ports 20, and a control unit is provided for controlling the output of the material container heating unit 11 or linking portion heating unit 16 correspondingly to the output signal of the detection unit. The detection unit is a film thickness monitor using a quarts oscillator.

During vapor deposition, the distance between the substrate 30 and the plurality of release ports 20 was set to 200 mm, and film formation was performed, while moving the substrate 30 held in the substrate holder (substrate holding mechanism) in the horizontal direction (vertical direction in the figure) at a rate of about 2 mm/sec. The plurality of release ports 20 were disposed along the side direction of the substrate 30 and a uniform film was formed on the entire surface of the substrate 30 by carrying the substrate 30 in the direction perpendicular to the arrangement direction of the release ports 20.

A process performed to replenish the film-forming material in the material container after the predetermined film has been formed will be described below in greater detail.

The material container 10 was a small titanium crucible with an inner diameter of 40 mm and a depth of 100 mm, and 60 g of alumiquinolinole complex (Alq3) was accommodated therein.

First, the continuous film formation process will be described.

In the continuous film formation process, a film was continuously formed on the substrate 30 at an evaporation rate of about 10 Å/sec at a temperature of the material container heating unit 11 of about 300° C., a temperature of the linking portion heating unit 16 of about 320° C., and a temperature of the transport pipe heating unit 15 of about 280° C.

The temperature distribution in the transport pipe in this case was ±10° C., the film-forming material did not condensate in the transport pipe in the film forming process, and the rate was stable.

The temperature of the linking portion heating unit 16 was set higher than that of the material container heating unit 11, thereby controlling only the vicinity of the evaporation surface of the film-forming material 12 contained in the material container 10 to a temperature necessary for the predetermined evaporation and continuously maintaining the film-forming material that does not participate in evaporation at a comparatively low temperature.

A process of stopping the film formation will be explained below.

After the film formation has been continued for about 100 h under the above-described conditions, an operation of replenishing the film-forming material in the material container 10 was performed.

The consumption rate of the material in the material container 10 during film formation was about 0.5 g/h, about 50 g was consumed within 100 h, and the evaporation was stopped when about 10 g of the film-forming material 12 remained in the material container 10.

As shown in FIG. 3 and FIG. 4, the output of the material container heating unit 11 was stopped and then the output of the linking portion heating unit 16 was stopped to stop the evaporation inside the material container 10.

As a result, the evaporation rate immediately started to decrease and the evaporation stopped completely in about 0.5 h. Then, the output of the transport pipe heating unit 15 for heating the transport pipe 14 other than the vicinity of the linking portion was stopped. When the temperature in all zones inside the film forming chamber has dropped sufficiently, the film forming chamber 40 was opened to the atmosphere and the material container 10 was rapidly detached from the transport pipe 14.

The results of purity analysis of the film-forming material remaining in the detached material container 10 confirmed the purity at the same level as that of the unheated film-forming material. Further, no film-forming material adhered to the inner surface of the transport pipe 14 after the evaporation has been stopped, and the condensation inside the transport pipe could be prevented even when the evaporation was stopped. For this reason, even when the film-forming material was replenished to the detached material container 10 and the evaporation was restarted, the predetermined evaporation rate could be reached without any delay and a stable film formation process could be reproduced.

Thus, it was possible to increase uniformity of temperature in the transport pipe and reduce the pipe resistance. More specifically, because a uniform temperature distribution was obtained in the transport pipe, local condensation inside the pipe could be prevented. Further, the reduction in pipe resistance relaxed a thermal load on the material and could inhibit the material modification or change such as decomposition caused by thermal damage.

Further, the evaporation could be stopped and started within a short interval and the efficiency of the operation of replenishing the material in the material container could be increased, thereby increasing the apparatus operation efficiency.

### Example 2

In the present example, an organic compound layer constituting an organic EL panel was continuously formed using the film forming apparatus shown in FIG. 7.

The film forming chamber 40 is provided with two material containers 10, the transport pipe 14 having branch pipes 18 connected to respective material containers 10, a plurality of release ports 20 for releasing the vapor toward the substrate 30, and the linking portion 13 that enables the replacement of the material containers 10. Each material container 10 is provided with the material container heating unit 11 and the linking portion heating unit 16. The transport pipe 14 downstream of the vicinity of each linking portion 13 is heated with the transport pipe heating unit 15. Each branch pipe 18 is provided with a valve 17 for controlling the follow rate, and the operations of opening or shutting down the vapor flow from the material containers 10 can be independently adjusted. In FIG. 7, the vapor flow is shown by a broken line. In this state, one valve 17 is opened and the other valve 17 is closed. The film forming chamber 40 is evacuated by an evacuation unit to a vacuum degree of 10⁻⁴ Pa to 10⁻⁶ Pa.

The film forming chamber 40 is connected to the material container replacement chamber 50 via a gate valve 52. In order to replace the material container 10 in the film forming chamber 40 and material container replacement chamber 50, an automatic robot (not shown in the figure) is disposed that conveyers the material container in a standby state to a predetermined position. A total of two material container holders 51 (for sake of convenience, only one holder is shown in the figure) are disposed in the material container replacement chamber 50. One holder is used as a site for placing a material container for a standby state, and the other holder is used as a site for temporarily holding the material container removed from the film forming chamber 40. A heating unit for preheating the material container 10 in a standby state is provided in the material container holder 51 for a standby state. Further, an automatic robot (not shown in the figure) is also provided that can randomly transfer the material container 10 to any of the two material container holders 51.

A process of replacing the material container with another material container via the material container replacement chamber 50 after the formation of the predetermined film has been completed in the material container 10 will be explained below in greater detail.

Each material container 10 was a small titanium crucible with an inner diameter of 40 mm and a depth of 100 mm, and 60 g of alumiquinolinole complex (Alq3) was accommodated therein. The material container 10 had an outer shape provided with a neck to facilitate grasping by the automatic robot.

The continuous film formation process will be explained below.

A film is formed on the substrate 30 by using one material container 10, and in this period the formation of film with the other material container 10 is stopped. Film formation start and stop from each material container 10 is conducted by using valves 17 disposed for each material container 10 and switching between the open and closed states of the flow channel.

A state of forming a film by using one material container 10 will be explained below.

Thus, a film was continuously formed on the substrate 30 at an evaporation rate of about 10 Å/sec at a temperature of the material container heating unit 11 of about 300° C., a temperature of the linking portion heating unit 16 of about 320° C., and a temperature of the transport pipe heating unit 15 of about 280° C. Because the evaporation from the other material container 10 is unnecessary within this period, heating with the other material container heating unit 11 and linking portion heating unit 16 was not conducted.

The temperature distribution in the transport pipe 14 that conveyed the vapor from one material container 10 in this case was ±10° C., the film-forming material did not condensate in the transport pipe in the film forming process, and the rate was stable.

The temperature of the linking portion heating unit 16 was set higher than that of the material container heating unit 11, thereby controlling only the vicinity of the evaporation surface of the film-forming material 12 contained in the material container 10 to a temperature necessary for the predetermined evaporation and continuously maintaining the film-forming material that does not participate in evaporation at a comparatively low temperature.

A process of stopping the film formation will be explained below.

Immediately before the formation of film from one material container 10 has been stopped, the heating with the material container heating unit 11 and linking portion heating unit 16 of the other material container was started.

One valve 17 was then shut down to stop the continuous formation of film with the material container 10 and the other valve 17 was opened at the same time. The material container heating unit 11 of the other container was set to 300° C., the linking portion heating unit 16 was set to 320° C., and the evaporation rate from the other material container 10 heated heretofore to the predetermined temperature was detected with the detection unit 60. The time consumed to switch the material containers that were used for forming the film under the valve control was about 1 min for each valve. Therefore, switching of the material containers 10 could be implemented practically without interrupting the formation of film on the substrate 30.

In order to stop the evaporation in the material container 10 that has stopped forming the film, first, the output to the material container heating unit 11 was stopped and then the output to the linking portion heating unit 16 was stopped.

The consumption rate of the material in the material container 10 during film formation was about 0.5 g/h, about 50 g was consumed within 100 h, and the evaporation was stopped when about 10 g of the film-forming material 12 remained in the material container 10.

As a result, the evaporation rate in the material container 10 immediately started decreasing and the evaporation stopped completely in about 0.5 h.

The gate valve 52 was then opened and the material container 10 in which the evaporation has stopped was detached from the transport pipe 14 by the automatic robot and rapidly transferred to the material container holder 51 of the material container replacement chamber 50. Another material container 10 that has been heretofore prepared in the material container replacement chamber 50 was carried by the automatic robot to the film forming chamber 40 and linked to the linking portion 13. The gate valve 52 was then closed. In such a replacement operation period the material container replacement chamber 50 was controlled to have the degree of vacuum about equal that of the film forming chamber 40 and pressure fluctuations inside the film forming chamber 40 caused by opening and closing of the gate valve were inhibited.

The results of purity analysis of the film-forming material remaining in the detached material container 10 confirmed the purity at the same level as that of the unheated film-forming material. Further, no film-forming material adhered to the inner surface of the transport pipe 14 after the evaporation has been stopped, and the condensation inside the transport pipe could be prevented even when the evaporation was stopped. For this reason, even when the evaporation was restarted with the material container 10 that replaced the detached material container 10, the predetermined evaporation rate could be reached without any delay and a stable film formation process could be reproduced.

Thus, it was possible to increase uniformity of temperature in the transport pipe and reduce the pipe resistance. More specifically, because a uniform temperature distribution was obtained in the transport pipe, local condensation inside the pipe could be prevented. Further, the reduction in pipe resistance relaxed a thermal load on the material and could inhibit the material modification or change such as decomposition caused by thermal damage.

Further, the evaporation could be stopped and started within a short interval and the efficiency of the operation of replenishing the material in the material container could be increased, thereby increasing the apparatus operation efficiency. In addition, because the material container could be repeatedly replaced even during the long-term continuous film formation operation, it was not necessary to expose the film-forming material to a high temperature for a long time and a thermal load on the film-forming material in the manufacturing process could be further reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-001421, filed Jan. 7, 2009, which is hereby incorporated by reference herein in its entirety.

What is claimed is:

1. An apparatus comprising:
a holding mechanism that holds a substrate;
a material container where a film-forming material is gasified;
a release port for releasing the gasified film-forming material toward the substrate;
a material container heating unit for heating the material container;
a transport pipe that is detachably linked to the material container by a linking portion and serves to transport the gasified film-forming material from the material container to the release port;
a transport pipe heating unit for heating a remaining zone of the transport pipe other than a portion in a vicinity of the linking portion;
a linking portion heating unit that is disposed independently from the transport pipe heating unit and serves for heating the portion of the transport pipe in the vicinity of the linking portion; and
control unit for controlling the transport pipe heating unit and the linking portion heating unit.

2. The apparatus according to claim 1, further comprising:
a branch pipe that is branched off the transport pipe;
a recovery container disposed at a distal end of the branch pipe; and
a unit for shutting and opening a flow of the gasified film-forming material to the branch pipe.

3. The apparatus according to claim 2, wherein an inside of the recovery container is maintained at a temperature equal to or lower than an evaporation temperature of the film-forming material.

4. The apparatus according to claim 1, wherein the linking portion heating unit can raise a transport pipe temperature in the vicinity of the linking portion to a temperature higher than a transport pipe temperature of the remaining zone.

5. The apparatus according to claim 1, further comprising a plurality of material containers, wherein
the plurality of material containers are connected to a common release port via the transport pipe.

6. The apparatus according to claim 5, comprising a plurality of linking portion heating units for heating a linking portion disposed in each of the plurality of material containers.

7. The apparatus according to claim 6, comprising
a detection unit for detecting an evaporation rate of the gasified film-forming material that is transported from the plurality of material containers to the release port.

8. A method comprising:
disposing a substrate inside a film forming chamber;
heating a material container accommodating a film-forming material and gasifying the film-forming material; and
forming a film on the substrate by releasing the gasified film-forming material from a release portion toward the substrate via a transport pipe linked by a linking portion to the material container, wherein
a portion of the transport pipe in the vicinity of the linking portion, a remaining zone other than the portion in the vicinity of the linking portion; and the material container are independently temperature controlled.

9. The method according to claim 8, further comprising:
conducting control such that a temperature of the portion of the transport pipe in the vicinity of the linking portion and a temperature of the material container become higher than a temperature of the remaining zone.

10. The method according to claim 8, further comprising:
stopping the heating of the portion of the transport pipe in the vicinity of the linking portion after the heating of the material container has been stopped.

11. The method according to claim 10, further comprising:
providing a plurality of material containers filled with respective film-forming materials and sequentially stopping the heating of the material containers that completed forming the film.

12. The method according to claim 11, further comprising:
raising a temperature of the material container that started forming a film, from among the plurality of material containers, together with a temperature of the portion of the transport pipe in the vicinity of the linking portion.

13. A method for manufacturing an organic EL panel, comprising
forming a thin film of an organic EL device on the substrate by the method according to claim 8.

14. A method comprising:
gasifying a film-forming material in a material container;
releasing the gasified film-forming material toward a substrate by a release port;
heating the material container by a material container heating unit;
detachably linking a transport pipe to the material container by a linking portion;
transporting the gasified film-forming material from the material container to the release port; and
heating a remaining zone of the transport pipe other than a portion in a vicinity of the linking portion by a transport pipe heating unit.

15. The method according to claim 14 further comprising:
heating the portion of the transport pipe in the vicinity of the linking portion by a linking portion heating unit, the linking portion heating unit being disposed independently from the transport pipe heating unit; and
controlling the transport pipe heat unit and the linking portion heating unit.

16. The method according to claim 8, further comprising:
branching off a branch pipe from the transport pipe;
disposing a recovery containing at a distal end of the branch pipe by a recovery container;
shutting and opening a flow of the gasified film-forming material to the branch pipe.

17. The method according to claim 16, further comprising:
maintaining an inside of the recovery container at a temperature equal to or lower than an evaporation temperature of the film-forming material.

18. The method according to claim 14, further comprising:
raising a transport pipe temperature in the vicinity of the linking portion to a temperature higher than a transport pipe temperature of the remaining zone.

19. The method according to claim 14, further comprising:
detecting an evaporation rate of the gasified film-forming material.

20. The method according to claim 14, further comprising forming a thin film of an organic EL device on the substrate.
